(19) United States
(12) Patent Application Publication
(10) Pub. No.: US 2008/0099797 A1
(43) Pub. Date: May 1, 2008

(54) Method and device for sensing radiation

(76) Inventor: Douglas Kerns, Sierra Madre, CA (US)

Correspondence Address: Darryl G. Walker, Suite 235, 300 South First Street, San Jose, CA, 95113, US

(21) Appl. No.: 11/903,258

(22) Filed: Sep. 21, 2007

Related U.S. Application Data
(60) Provisional application No. 60/855,381, filed on Oct. 31, 2006.

(51) Int. Cl. H01L 31/112

(52) U.S. Cl. 257/258; 257/257; 257/E31.073

(57) ABSTRACT

A device is disclosed for sensing radiation, having a gate region and a substrate, wherein one of the gate region and the substrate is configured as an input for radiation. A channel region, connecting a source region and a drain region of the transistor device is provided. The device is configured to produce an electrical signal, which is proportional to the input radiation, at a first location of the channel region.

This application claims the benefit of U.S. Provisional Patent Application Ser. No. 60/855,381, filed Oct. 31, 2006, the contents of which are incorporated by reference herein.

### TECHNICAL FIELD

Methods and devices for sensing radiation are disclosed, along with modular implementations of such devices, appropriate for inclusion in an array of pixels.

### BACKGROUND OF THE INVENTION

Devices for sensing radiation are known. U.S. Pat. No. 5,528,059, assigned to Nikon entitled “Photoelectric Conversion Device Utilizing A JFET”, and the Nikon Corp. Web Page document entitled “The LBCAST JFET Image Sensor”, from www.nikon.co.jp dated Oct. 20, 2006, describe an amplification-type photoelectric conversion device utilizing a JFET in a read-out circuit for amplifying charges generated by a photodiode junction of a photoelectric conversion circuit. A three-phase read-out sequence involves use of a charge-dump phase. Thus, a continuous radiation detection cannot be accomplished and the device must be reset to restore the gate voltage to an initial condition before the next radiation sampling period can be performed. Furthermore, in the read-out sequence the gate of the JFET receives a potential by way of a boost capacitor having one terminal receiving a drive signal from a drive circuit and the other terminal connected to the gate of the JFET.

Devices for detecting radiation can be used in a variety of electronic devices including, but not limited to, cameras and scanners. For example, these devices can include arrays of sensors to capture images electronically. Radiation sensors are also used to provide industrial control. Similar sensors can also be used in the communications industry to transduce electrical signals from optical signals. The sensing devices used in any or all of these applications can include arrays of sensing devices, including single element devices, line-scanners, and/or multidimensional sensing arrays.

An individual sensor can provide an output for a pixel of an image sensing array. Where enhanced resolution is desired, such a sensing array can include an increased number of pixels. The more compact a pixel device is, the greater the density of sensing devices in an array, and thus the greater the resolution.

### SUMMARY OF THE INVENTION

A device is disclosed for sensing radiation, comprising: a gate region and a substrate, wherein one of the gate region and the substrate is configured as an input for radiation. A channel region, connecting a source region and a drain region of the transistor device is provided, the device being configured to produce an electrical signal, which is proportional to the input radiation, at a first location of the channel region.

A circuit device for sensing radiation is disclosed, comprising: a JFET transistor device having a gate region, a channel region, and a substrate; and a signal output circuit connected with the channel region for producing an electrical signal from the channel region which is proportional to radiation received by at least one of the gate region and the substrate.

A method for sensing radiation is also disclosed, the method comprising: establishing a transistor device having a gate region and a substrate; establishing a channel region used to connect a source region and the drain region of the transistor device; applying radiation to at least one of the gate region and the substrate; and providing an electrical signal proportional to the radiation at an output of the transistor device, the output being connected to the channel region.

A method for establishing a circuit design is disclosed, comprising: creating a library of modular circuit components, wherein at least one of the circuit components is a JFET device having a gate region, a channel region and a substrate; and selecting the circuit component for inclusion in an electrical circuit, such that in response to radiation applied to a first contact of the JFET device, a second contact of the JFET device provides an electrical signal output proportional to the radiation.

According to an embodiment, a device for sensing radiation may include a junction field effect transistor (JFET) having a first gate region formed on a substrate. The first gate region may be configured as an input for radiation. A channel region may electrically connect a source region and a drain region of the JFET. The input may be essentially floating to generate a potential dependent on the radiation intensity received. In this way an impedance of the channel region may be controlled to allow an intensity measurement without directly applying a potential to the input.

The JFET may include a second gate region formed between two insulating layers.

The radiation may be provided from a frontside of an integrated circuit including the JFET.

The radiation may be provided from a backside of the integrated circuit including the JFET.

The JFET may continuously sense radiation without a reset operation to erase a previous sensing operation.

A method for sensing radiation may include the steps of receiving radiation at a gate region of a JFET, the gate region being essentially floating, applying a bias potential to a source/drain region of the JFET, and reading a potential provided by a drain/source region of the JFET.

The gate region may be formed between a channel region of the JFET and a substrate and the radiation may be applied to a backside of an integrated circuit on which the JFET is formed.

The step of reading may further include receiving the potential provided by the drain/source region at a first terminal of an amplifier circuit and receiving a reference potential at a second terminal of the amplifier.

The method may include the step of providing the reference potential to a source/drain region to at least one other JFET.

The step of reading may include selectively providing the bias potential to a row line that is connected to the source/drain of the JFET.

The step of reading may include selectively connecting a column that is connected to the drain/source region of the JFET to the first terminal of the amplifier circuit.

### BRIEF DESCRIPTION OF THE DRAWINGS

FIG. 1A illustrates a cross-section of an exemplary n-channel sensing device for sensing radiation according to an embodiment.

FIG. 1B illustrates a cross-section of an exemplary p-channel sensing device for sensing radiation according to an embodiment.

FIG. 1C illustrates a cross-section of an exemplary n-channel sensing device for sensing radiation according to an embodiment.

FIG. 1D illustrates a cross-section of an exemplary p-channel sensing device for sensing radiation according to an embodiment

FIG. 2 shows an exemplary embodiment of a sensing device which can be implemented using the n-channel device of FIG. 1A or the p-channel device of FIG. 1B.

FIGS. 3 and 4 show exemplary embodiments of an array of sensing devices.

### DETAILED DESCRIPTION OF THE EMBODIMENTS

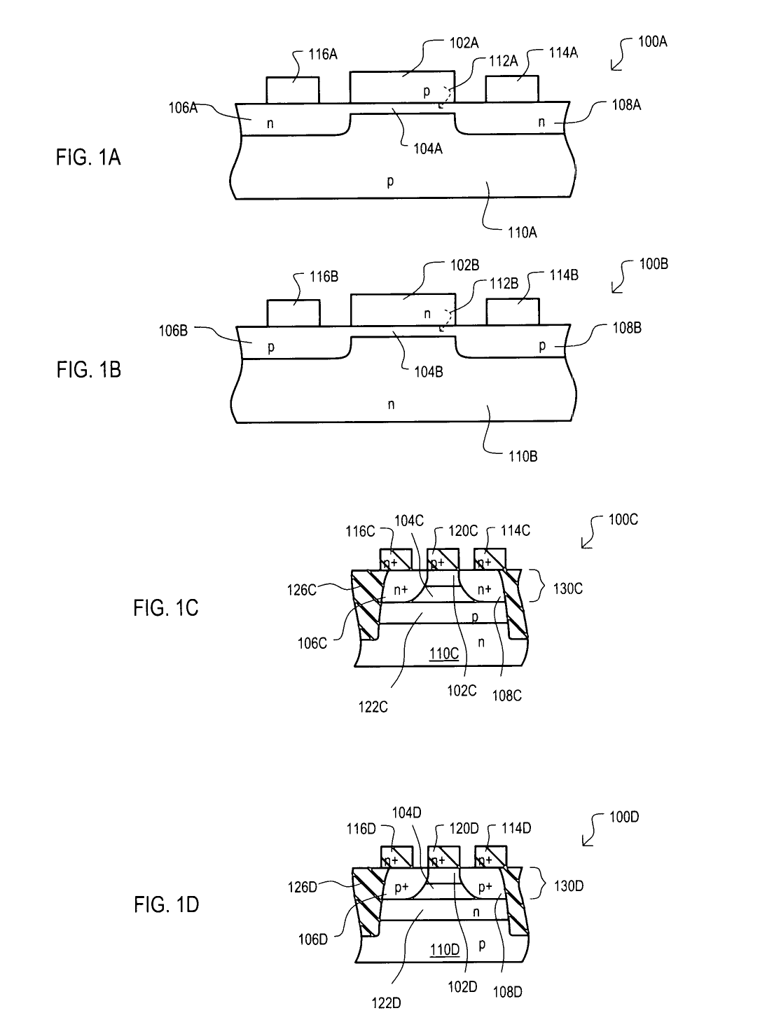

FIG. 1A illustrates a cross-sectional view of an exemplary device 100A for sensing radiation including, but not limited to, any particle, charged or uncharged, of sufficient energy to generate a photocharge. The particle can be associated, for example, with visible or infrared light or any other electromagnetic radiation. The device can be configured as a junction field effect transistor (JFET) device. The JFET can be configured to operate at desired voltage levels (e.g., 0 to 0.5 volts, or lesser or greater). The JFET 100A includes a gate region 102A and a substrate 110A, wherein the gate region 102A is configured as an input for radiation. The gate region 102A can be configured, for example, of p-type conductivity material.

The JFET 100A includes a channel region 104A, connecting a source region 106A and a drain region 108A of the transistor device. The channel region can provide an electrical signal as an output of a first location, such as at the source region 106A or drain region 108A.

In the exemplary FIG. 1A device, a current supplied across the channel region 104A is substantially independent of a current supplied between the gate region and a bulk region of the substrate. That is, a current I_{DS} is substantially independent of a current I_{GB}. The device is thereby configured to include a channel region, connecting a source region and a drain region of the transistor device, with a current supplied across the channel region being substantially independent of a current supplied between the gate region and a bulk region of the substrate. The device is configured to produce an electrical signal at a first location of the channel region, which is proportional to the input radiation.

As referenced herein, the phrase “substantially independent” means that the current passing across the channel region 104A (e.g., from drain to source), does not significantly interact with current passing between the gate region 102A and the bulk region of substrate region 110A so as to significantly affect one another. That is, charges of one current do not interact directly with charges of the other current. However, a voltage (e.g., voltage from gate-to-channel, such as the gate-to-source voltage V_{GS}) will be influenced by either current, and any change in the voltage will influence the other current. The current passing across the channel region 104A versus the current passing from the gate region 102A to the substrate 110A are considered to be electrically orthogonal. In the exemplary embodiment shown, these current paths also happen to be geometrically perpendicular.

The JFET transistor device 100A as configured in accordance with exemplary embodiments described herein, functions as both a bipolar junction transistor (BJT) and as a JFET simultaneously to provide the substantially independent currents that are electrically perpendicular. Those skilled in the art will appreciate the aforementioned reference to the geometrical perpendicularity of the FIG. 1 transistor device is by way of example only. That is, off angle configurations of the channel region relative to a path from the gate to the bulk region of the substrate 110A can be implemented and are encompassed by exemplary embodiments described herein.

The substantial independence of the two electrically perpendicular current paths is reflected in the following equations:
Bipolar Function: Gate-Bulk Current (I_{GB}):

I_{GB}=I₀exp(V_{GS}/U_{T})
JFET Function: Drain-Source Current (IDS)

(Triode region, where V_{DS} is small) I_{DS}=βV_{DS}(V_{GS}−V_{T})

(saturation, where V_{DS} is large) I_{DS}=β(V_{GS}−V_{T})²

In the foregoing equations, V_{DS} is the drain-to-source voltage and U_{T} is a scale factor, which depends on device temperature. The value U_{T} has been referenced in other literature as a value “V_{T}”. See, for example, Paul R. Gray, Paul J. Hurst, Stephen H. Lewis, Robert G. Meyer; Analysis and Design of Analog Integrated Circuits; fourth edition, John Wiley and Sons Inc., New York, N.Y. 2001.

As referenced herein:

$${U}_{T} = \frac{kT}{electronic charge}$$

where k is Bolzman's constant and T is absolute temperature. In the foregoing equations, the value “U_{T}” is distinguished from the scale factors labeled I₀ and V_{T}. That is, in the foregoing equations, I₀ and V_{T} are scale factors which depend on the fabrication process. β is a scale factor which depends both on the fabrication process and on the geometric design of the device 100A.

As discussed, the foregoing equations represent two modes of operation: a first bipolar (BJT) mode of operation associated with the gate-to-source junction and the current I_{GB}; and a second mode of JFET operation associated with the source-to-drain channel and the current I_{DS}.

The foregoing equation for I_{DS} assumes the transistor is operating in saturation. In addition, where the drain voltage and the source voltage are approximately equal, the channel can be considered to function as a resistor in its behavior. Because the channel current IDS is substantially independent of the gate to bulk current I_{GB}, the currents can be independently controllable. However, both will operate in dependence upon the gate to source voltage V_{GS}. As mentioned, the currents of the FIG. 1A example can thereby influence, or be influenced by V_{GS}.

Application of a bias voltage to, for example, the source region of FIG. 1A can be used to establish a threshold for a read out (i.e., interrogation) of the sensing device. The bias voltage will affect a barrier height of the channel region and thereby control the flow of charge carriers crossing between the gate region and a bulk region of the substrate. As already mentioned, this current between the gate region and the bulk region can affect the voltage V_{GS} across the gate region to the channel region which, in turn, will affect charge carriers flowing across the channel region.

In an exemplary circuit device where an electrical power supply voltage is relatively small, signal values can be represented as currents, rather than as voltages. A current input can be produced as a function of incident radiation using the exemplary FIG. 1A device. The FIG. 1A transistor device supports the aforementioned two perpendicular current paths, wherein a magnitude of one current can strongly influence the magnitude of the other to provide the radiation sensing feature described herein.

In the FIG. 1A embodiment, the gate region 102A can be configured, for example, of p-type conductivity material. The channel region 104A that connects the source region 106A and the drain region 108A of the transistor device is formed as an n-type channel of n-type conductivity material.

In the FIG. 1A exemplary embodiment, the gate region 102A joins the channel region 104A through a p-n junction, such that minority charge carriers can be generated in the gate region and then move into the channel region from the gate region, provided a suitable voltage difference exists between the gate region and channel regions. The dashed arrow 112A in FIG. 1A schematically illustrates the trajectory of positive charge carrier from the gate region 102A into the channel region 104A, and then on to a p-type bulk region of the substrate 110A on the other side of the channel region 104A.

The minority carriers generated in the gate region can result from incident photons or by other radiation. The minority charge carriers within the gate region can then move into the channel region. Similarly, positive charge carriers generated in the channel region can cross into the gate region. The movement of minority charge carriers from the gate region into the channel region constitutes an electrical current, referred to herein as a photo current.

The movement of charge carriers into the p-type bulk region constitutes an electrical current, referred to herein as a “BJT current”, described by the foregoing equation for I_{GB}. The current is analogous to the collector current of a bipolar junction transistor, and can be controlled by the voltage difference between the gate region 102A and the channel region 104A (e.g., the gate-to-source voltage V_{GS}). A strong non-linear function to this voltage difference exists. Given the strong non-linear dependence, a voltage between the gate region 102A and a source region 106A of the JFET transistor device 100A will dominate control for the BJT current I_{GB}.

The FET gate-to-source voltage V_{GS} depends primarily on the FET channel current I_{DS}. The dependency can, in an exemplary embodiment, be a relatively weak, non-linear function.

In the absence of other influences, the photo current will continue to transport charges between the channel region and the gate region, charging the value of V_{GS} between the gate region and the channel region, until V_{GS} is sufficiently large to induce an opposing current flow equal in magnitude to the photo current. The resulting steady-state gate-to-channel voltage V_{GS} is therefore a function of the photo current. This photo current is, in turn, directly proportional to the incident flux of photons or other radiation on the gate region.

Those skilled in the art will appreciate that although radiation of the FIG. 1A embodiment is illustrated as being applied to the gate region, this radiation can alternately be applied to a bulk region of the substrate. When the input is to be supplied to the gate (bulk) region, the gate (bulk) region can be floating. As referenced herein, a “floating” potential means that a contact connected to, for example, the gate region 102A, is left unconnected (i.e., open). Where the radiation is applied to the gate region, the bulk region can be tied to a circuit common, or ground. Alternately, where the input radiation is applied to the bulk region, the gate region can be connected to a circuit common.

In yet other embodiments, both the gate region 102A and the bulk region 110A may be allowed to float in a radiation detector 100A.

JFET device comprising a radiation detector 100A may detect radiation in the following manner. A depletion region may be formed between the n-type channel region 104A and the p-type gate region 102A. Electromagnetic waves (radiation applied to the device) may strike the depletion region with sufficient energy to create electron-hole pairs. An electric field in the depletion region may drive the electrons to the n-type channel region and the holes to the p-type gate region 102A. Thus, the created electron-hole pair may be separated before recombination and may form a current to charge the gate region 102A. This voltage can be limited to the potential barrier of the p-n junction formed by the gate region 102A and channel region 104A, which is about 0.6 volts. However, due to parasitic leakage, the generated voltage on gate region 102A may achieve a quiescent state, which may vary due to temperature, area of the p-n junction formed by gate terminal 102A and channel region 104A and/or other factors. However, the generated voltage on gate region 102A may be proportional to the intensity of the radiation received.

In the configuration described above with the gate region 102A floating, the photodetector cell comprising a JFET 100A can operate to continuously detect radiation in a photovoltaic mode of operation. For example, when radiation having a lower intensity is received by the JFET 100A, the voltage of the gate region 102A may equalize at a lower voltage as compared to when radiation having a higher intensity is received by the JFET 100A. In this way, the voltage on the gate region 102A may be proportional to the intensity of the received radiation.

By settling to a quiescent state potential at the gate region 102A, the device may continuously detect radiation without the necessity of resetting (i.e. by way of a reset operation) the detector before the next exposure.

The potential of the gate region 102A controls the impedance of the channel region 104A formed between the source region 106A and the drain region 108A. Therefore, by essentially measuring the impedance of the channel region 104A, the intensity of the radiation detected can essentially be measured. It should be noted that no potential may be applied to the gate region 102A. Instead a potential is developed due to the radiation received as compared to U.S. Pat. No. 5,528,059 in which a potential is capacitively coupled to the JFET gate region during a read out procedure.

In accordance with exemplary embodiments, the JFET transistor device 100A includes a first contact 114A of the channel region 104A for providing an output signal. The contact used for the output signal can be associated with either the drain region or the source region.

A second contact 116A of the channel region 104A provides for receiving a bias voltage. Of course, where the bias voltage is applied to the drain region, then the source region can function as a signal input. In exemplary embodiments, the output signal represents a signal proportional to the incident radiation, wherein a read-out is controlled as a function of the bias voltage.

In the FIG. 1A embodiment, the bulk region can be grounded, and the gate region can be left floating to receive incident radiation. Of course, the foregoing voltage values are by way of example only and can be any suitable voltage selected by a circuit designer.

As mentioned, the ability to provide an output current signal from the channel that is related to amplitude/intensity of a radiation signal applied to the gate region results from the JFET 100A performing the functions of two separate devices: a JFET device and a bipolar junction transistor (BJT) device. Because the gate region 102a joins the channel 104A through a p-n junction, negative charge carriers generated in the gate region 102 can cross to the channel region 104A and into the bulk region of substrate 110A. As already discussed, the movement of minority charge carries as a current from the gate region 102A into the channel 104A will, in the absence of other influences, transport charge from the channel 104A to the gate region 102A. This will charge a voltage at the gate relative to the channel (e.g., a gate-to-source voltage V_{GS}) and influence the amplitude of current across the channel region.

FIG. 1B shows a circuit similar to FIG. 1A. However, in the FIG. 1B embodiment, the transistor device 100B is a p-channel structure, with opposite-sensed charge carriers. Transistor device 100B comprising a radiation sensing device may include similar constituents as transistor device 100A. Such constituents may have the same first 3 digits, but end in a “B” instead of an “A” and may have an opposite conductivity type. P-type becomes n-type and n-type becomes p-type.

Transistor device 100B includes a gate region 102B, a drain region 108B, a source region 106B, and a channel region 104B formed on a substrate 110B. Substrate 110B and gate region 102B may be doped n-type. Drain region 108B, source region 106B, and channel region 104B may be doped p-type. In this way, transistor device 100B may be a p-channel JFET.

P-channel JFET 100B may operate in a similar manner when used as a photodetector (radiation detector) cell. Gate region 102B may be essentially floating.

In the configuration described above, with the gate region 102B floating, the photodetector cell comprising a JFET 100B can operate to continuously detect radiation in a photovoltaic mode of operation. For example, when radiation having a lower intensity is received by the JFET 100B, the voltage of the gate region 102B may equalize at a less negative voltage (with reference to source region 108B) as compared to when radiation having a higher intensity is received by the JFET 100B. In this way, the magnitude of the gate to source voltage on the gate region 102B may be proportional to the intensity of the received radiation.

By settling to a quiescent state potential at the gate region 102B, the device may continuously detect radiation without the necessity of resetting the detector before the next exposure.

The potential of the gate region 102B controls the impedance of the channel region 104B formed between the source region 106B and the drain region 108B. Therefore, by essentially measuring the impedance of the channel region 104B, the intensity of the radiation detected can essentially be measured. It should be noted that no potential may be applied to the gate region 102B. Instead a potential is developed due to the radiation received as compared to U.S. Pat. No. 5,528,059 in which a potential is capacitively coupled to the JFET gate region during a read out procedure.

Referring now to FIG. 1C, yet another embodiment of a device for sensing radiation is set forth in a cross-sectional schematic diagram and given the general reference character 100C.

The transistor device 100C comprising a radiation sensing device may include similar constituents as transistor device 100A. Such constituents may have the same first 3 digits, but end in a “C” instead of an “A”.

Transistor device 100C may differ from transistor device 100A in that a second gate region 122C may be formed under the channel region 104C and on the substrate 110C. Transistor device 100C may also include isolation regions 126C formed by a shallow trench isolation (STI) method or the like.

Transistor device 100C may include a source terminal 116C, a drain terminal 114C, and a gate terminal 120C. The source terminal 116C and drain terminal 114C may be formed from n-type polysilicon, as just one example. The gate terminal 120C may be formed from p-type polysilicon. A diffusion step or the like may be used to form n-type source region 106C, n-type drain region 108C, and p-type gate region 102C by way of out diffusion from source terminal 116C, a drain terminal 114C, and a gate terminal 120C, respectively. The channel region 104C and substrate may be n-type and the gate region 122C may be p-type.

With the essentially floating gate region 122C, holes created by electromagnetic waves may be collected by the floating gate region 122C as well as gate region 102C.

In the configuration described above with the gate regions (102C and 122C) floating, the photodetector cell comprising a JFET 100C can operate to continuously detect radiation in a photovoltaic mode of operation. For example, when radiation having a lower intensity is received by the JFET 100C, the voltage of the gate regions (102C and 122C) may equalize at a lower voltage as compared to when radiation having a higher intensity is received by the JFET 100C. In this way, the voltage on the gate regions (102C and 122C) may be proportional to the intensity of the received radiation.

By settling to a quiescent state potential at the gate regions (102C and 122C), the device may continuously detect radiation without the necessity of resetting the detector before the next exposure.

The potential of the gate regions (102C and 122C) controls the impedance of the channel region 104C formed between the source region 106C and the drain region 108C. Therefore, by essentially measuring the impedance of the channel region 104C, the intensity of the radiation detected can essentially be measured. It should be noted that no potential may be applied to the gate regions (102C and 122C). Instead a potential is developed due to the radiation received.

Furthermore, because a depletion region may be formed between the channel region 104C and gate region 102C and a depletion region may be formed between the substrate 110C and gate region 122C, efficiency of the photodetector (i.e. radiation detector) may be improved. In particular, the gate region 122C may have a depletion region on an upper surface formed between the gate region 122C and the source region 106C, drain region 108C, and the channel region 104C and a depletion region formed between the gate region 122C and the substrate 110C, efficiency may be improved.

Referring now to FIG. 1D, yet another embodiment of a device for sensing radiation is set forth in a cross-sectional schematic diagram and given the general reference character 100D.

The transistor device 100D comprising a radiation sensing device may include similar constituents as transistor device 100B. Such constituents may have the same first 3 digits, but end in a “D” instead of an “B”.

Transistor device 100D may differ from transistor device 100B in that a second gate region 122D may be formed under the channel region 104D and on the substrate 110D. Transistor device 100D may also include isolation regions 126D formed by a shallow trench isolation (STI) method or the like.

Transistor device 100D may include a source terminal 116D, a drain terminal 114D, and a gate terminal 120D. The source terminal 116D and drain terminal 114D may be formed from p-type polysilicon, as just one example. The gate terminal 120D may be formed from n-type polysilicon. A diffusion step or the like may be used to form p-type source region 106D, p-type drain region 108D, and n-type gate region 102D by way of out diffusion from source terminal 116D, a drain terminal 114D, and a gate terminal 120D, respectively. The channel region 104D and substrate may be p-type and the gate region 122D may be n-type.

With the essentially floating gate region 122D, electrons created by electromagnetic waves may be collected by the floating gate region 122D as well as gate region 102D.

In the configuration described above with the gate regions (102D and 122D) floating, the photodetector cell comprising a JFET 100D can operate to continuously detect radiation in a photovoltaic mode of operation. For example, when radiation having a lower intensity is received by the JFET 100D, the voltage of the gate regions (102D and 122D) may equalize at a lower magnitude voltage as compared to when radiation having a higher intensity is received by the JFET 100D. In this way, the voltage on the gate regions (102D and 122D) may be proportional to the intensity of the received radiation.

By settling to a quiescent state potential at the gate regions (102D and 122D), the device may continuously detect radiation without the necessity of resetting the detector before the next exposure.

The potential of the gate regions (102D and 122D) controls the impedance of the channel region 104D formed between the source region 106D and the drain region 108D. Therefore, by essentially measuring the impedance of the channel region 104D, the intensity of the radiation detected can essentially be measured. It should be noted that no potential may be applied to the gate regions (102D and 122D). Instead a potential is developed due to the radiation received.

Furthermore, because a depletion region may be formed between the channel region 104D and gate region 102D and a depletion region may be formed between the substrate 110D and gate region 122D, efficiency of the photodetector (i.e. radiation detector) may be improved. In particular, the gate region 122D may have a depletion region on an upper surface formed between the gate region 122D and the source region 106D, drain region 108D, and the channel region 104D and a depletion region formed between the gate region 122D and the substrate 110D, efficiency may be improved.

In the embodiments of FIGS. 1C and 1D, by providing gate regions (122C and 122D) a radiation source, such as a focused image from a camera, may be applied to a backside (i.e. from the substrate (110C and 110D) side of the integrated circuit. This may provide advantages by allowing wiring layers, bond wires, and the like on a frontside of the integrated circuit while providing radiation (typically in the form of light) on the backside of the integrated circuit.

Alternatively, in the embodiments of FIGS. 1A to 1B, the radiation may be provided on the frontside of the integrated circuit. In this case, it may be necessary to avoid unduly blocking the path of the radiation with wiring layers.

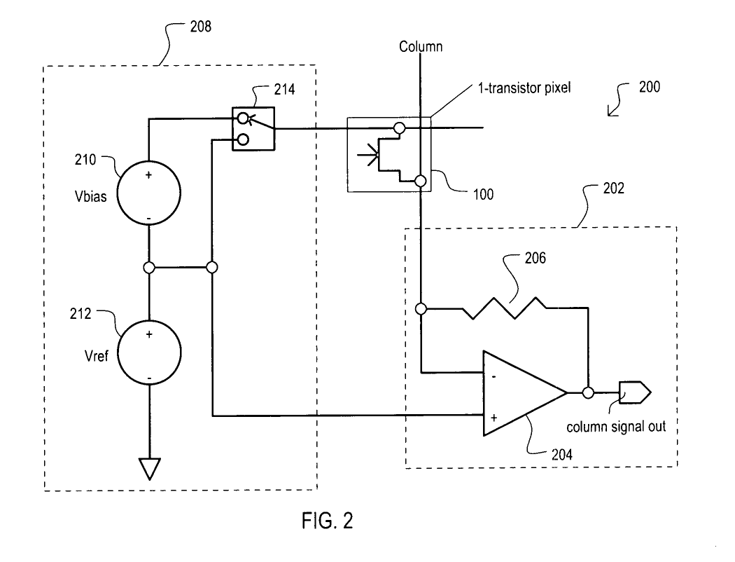

In the embodiments of FIGS. 1C and 1D, the gate regions (122C and 122D) may be isolated on their side surfaces by insulating layers formed in isolation regions (STI 126C and 126D, respectively). The insulating layers may be formed from silicon dioxide in a STI structure, or the like. The exemplary transistor devices as configured in FIGS. 1A, 1B, 1C, and 1D can be used in a variety of circuits to exploit the sensing function. One such example, is the sensing circuit illustrated in FIG. 2.

FIG. 2 illustrates an exemplary embodiment of a sensing device which can be implemented using the n-channel device of FIG. 1. The FIG. 2 circuit device 200 includes a JFET transistor device (radiation sensing device) 100 which can be configured as any of JFETS (100A, 100B, 100C, or 100D) of FIGS. 1A. The JFET includes a gate region, a channel region and a substrate as previously described.

In an exemplary embodiment, the signal output circuit, such as a signal output circuit 202, can be connected to the channel region of the transistor device 100 for producing an electrical signal from the channel region of the transistor device 100 which is proportional to radiation received by at least one of the gate region and the substrate. In the exemplary FIG. 2 embodiment, the signal output circuit includes an operational amplifier 204 having a feedback resistor 206. However, those skilled in the art will appreciate that any output circuit can be used to amplify an output of the transistor device in response to incident radiation on the gate.

As already mentioned, the output signal supplied from the transistor device 100 can be provided from a contact at either the source or drain region of the transistor. Regardless of which region is selected, the other region can be biased using a bias circuit 208.

In the exemplary FIG. 2 embodiment, the bias circuit 208 includes a voltage bias generator 210 and a voltage reference generator 212. A switch 214 is also included. The switch 214 can selectively apply the voltage bias of the voltage bias generator 210 to a contact of the channel region (i.e., to either the source, or drain region as appropriate). Alternately, the switch 214 can be used to apply the voltage reference without inclusion of the bias voltage, to this contact of the channel region.

The voltage reference from the voltage reference generator 212 can also be supplied to an input of the operational amplifier 204. For example, the voltage reference can be applied to a positive input of the operational amplifier 204 for differential comparison with an output from the transistor device 100.

The switch 214 can, for example, be configured using a transistor device such as the device 100. In this configuration, the gate region of the JFET device used as switch 214 can receive a decode signal, such as a row decode signal, to selectively provide the bias voltage from voltage bias generator 210 to the drain terminal of the radiation sensing device 100. By providing a signal to the gate terminals of JFET devices used for circuitry throughout the circuit device 200, any radiation absorbed by these JFET devices would not have an appreciable effect on the operation of the circuitry in which they are used.

In the exemplary embodiment, the bias voltage can be on the order of 5 millivolts to 100 millivolts, or within any desired range depending on the application. In addition, any number of the circuit devices shown in FIG. 2 can be combined to form an array of sensing devices for a one-dimensional or multi-dimensional sensing device.

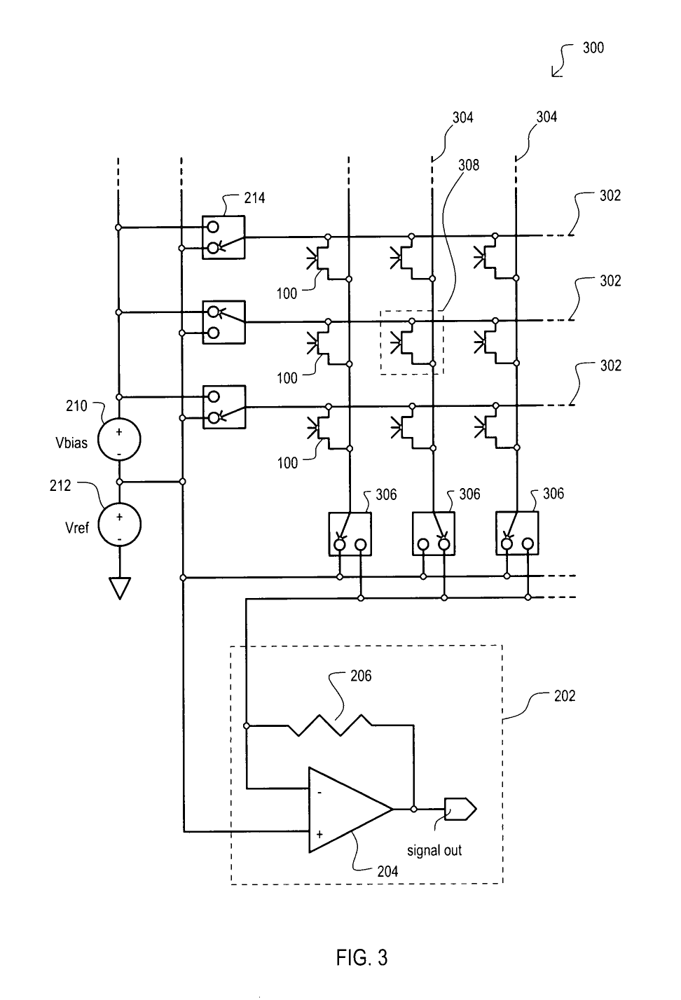

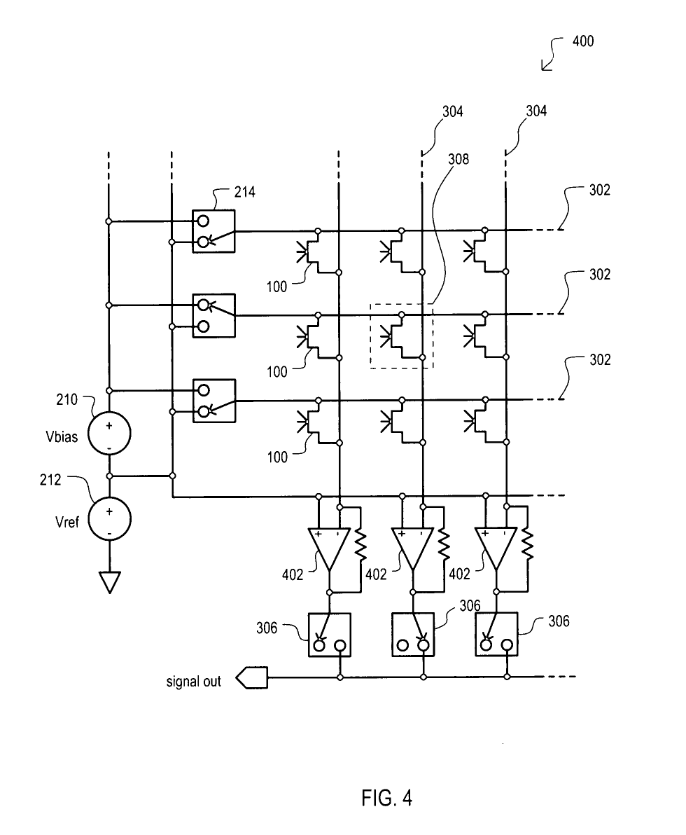

When included in an array, the multiple sensors can be interrogated using known electrical circuitry to estimate flux incident on the gate region (or bulk region) of the transistor device. The interrogation device and method illustrated in FIG. 2 can be used for a two-dimensional image sensing array, such as is illustrated in FIGS. 3 and 4.

In the FIG. 2 illustration, a single pixel representative of a position on an arbitrary two-dimensional array is shown. To interrogate this pixel, a first contact connected, for example, to the drain region, can be switched from the reference voltage to the bias voltage. The pixel gate voltage is a function of incident flux at the transistor device 100 used to form the pixel. The pixel gate voltage in turn determines conductance from the bias voltage to a column read out transimpedance.

Thus, a single transistor can be used as a pixel of a sensing array, wherein incident radiation is assessed as an output electrical signal using a non-destructive technique. Exemplary embodiments accumulate charge from incident radiation across a gate to channel capacitance (i.e., a p-n junction). Each single pixel can be considered a cell of an array whose output is an electrical signal proportional to the incident radiation.

In accordance with exemplary embodiments, because the entire gate region can be exposed to incident radiation, an entire active region of a transistor can be made sensitive to the input. This can optimize the density of an array formed using multiple transistor devices as described herein. The non-destructive read-out can be used in conjunction with known-read-out circuitry to provide multiple dimensional capability.

FIG. 3 shows an exemplary two-dimensional image sensing array configured using transistor devices 100, such as transistor device 100A, 100B, 100C, or 100D of FIGS. 1A, 1B, 1C, or 1D. In the FIG. 3 array 300, multiple rows 302 are illustrated, along with multiple columns 304. The transistor devices 100 are placed at intersections of the columns and rows. Each row 302 can include a switching device, such as switching device 214 as described with respect to FIG. 2, for selectively applying a bias voltage from a bias voltage generator 210 and/or a reference voltage from a reference voltage generator 212 to the row. An output amplifier 204 with a feedback resistor 206, as described with respect to FIG. 2, can be included to provide a read out in response to an interrogation of a particular cell including a transistor device 100. To provide this selective output from the multiple columns shown, a switching device 306 can be associated with each column.

The dashed lines indicate that the array 300 can be extended to larger dimensions than the three-by-three array shown. The switches 214, 306 are illustrated as being set in positions to accommodate an interrogation of the transistor device 100 associated with the pixel 308. The switches can be selectively controlled to provide read out from any pixel or pixels of the array.

FIG. 4 shows an alternate embodiment of a two-dimensional image sensing array 400. In FIG. 4, elements similar to those described with respect to FIG. 3 are similarly labeled. However, in the FIG. 4 embodiment, the signal output circuit includes multiple operational amplifiers 402 for each column of the array. That is, a separate output amplifier is provided for each column, as opposed to using a single amplifier shared across the entire array. Those skilled in the art will appreciate that numerous variations of such a multi-dimensional sensing array can be implemented, and those illustrated in FIGS. 3 and 4 are by way of example only.

An exemplary method for sensing radiation is also disclosed herein. In the exemplary embodiment, a transducer device having a gate region and a substrate is established. A channel region is established, and is used to connect a source region and a drain region of the transistor device. Radiation is applied to at least one of the gate region and the substrate. An electrical signal proportional to the radiation at an output of the transistor device can be provided, the output being connected to the channel region.

Those skilled in the art will appreciate that the material selected for configuration of the sensing device can be of any known type. In alternate embodiments, strained silicon can optionally be used to form a layer on the substrate beneath the gate region in an effort to improve conductivity of the channel region. Referring to FIG. 1A, an optional strained silicon layer can be deposited on the substrate bulk region 110A to form the channel 104A. Such an option can enhance transistor signal gain in a reduced size transistor device.

In alternate embodiments, a circuit design can be established using a method which involves the transistor device as described herein. In such a method, a library of modular circuit components can be created, wherein at least one of the circuit components is a JFET device having a gate region, a channel region and a substrate. In accordance with an exemplary embodiment, the circuit component can be selected for inclusion in an electrical circuit, such that in response to radiation applied to a first contact of the JFET device, a second contact of the JFET device produces an electrical signal output proportional to the radiation.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

Reference in the description to “one embodiment” or “an embodiment” means that a particular feature, structure, or characteristic described in connection with the embodiment is included in at least one embodiment of the invention. The appearance of the phrase “in one embodiment” in various places in the specification do not necessarily all refer to the same embodiment. The term “to couple” or “electrically connect” as used herein may include both to directly and to indirectly connect through one or more intervening components.

Further it is understood that the embodiments of the invention may be practiced in the absence of an element or step not specifically disclosed. That is an inventive feature of the invention may include an elimination of an element.

While various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A device for sensing radiation comprising:
a junction field effect transistor (JFET), including
a first gate region formed on a substrate, wherein the first gate region is configured as an input for radiation; and
a channel region, electrically connecting a source region and a drain region of the JFET, wherein the input is essentially floating to generate a potential dependent on the radiation intensity received thereby controlling an impedance of the channel region to allow an intensity measurement without directly applying a potential to the input.

2. The device of claim 1, wherein the input signal radiation is light.

3. The device of claim 1, wherein the JFET further includes a second gate region located on an opposite side of the channel region from the first gate region.

4. The device of claim 3, wherein the radiation is supplied to the backside of the device.

5. The device of claim 3, comprising:
the second gate region is isolated on at least one side by an insulating layer.

6. The device of claim 1, further including a bias voltage coupled to the drain region of the JFET.

7. The device of claim 1, wherein the bias voltage is used with a reference voltage to control a read out of the JFET.

8. The device of claim 1, wherein the radiation is infrared light.

9. The device of claim 1, wherein current produced by the radiation supplied to the gate region influences a voltage at the gate region to thereby affect an impedance of the channel region.

10. A circuit device for sensing radiation, comprising:
a junction field effect transistor (JFET) device having a gate region, a channel region, formed on a substrate that can continuously sense radiation without a reset operation to erase a previous sensing operation.

11. The circuit device of claim 10, wherein the radiation is supplied to the gate region and the gate region is essentially floating.

12. A junction field effect transistor (JFET), comprising:
a first gate region that is essentially floating formed between isolation structures, the gate region generates a potential in response to received radiation.

13. The JFET of claim 12, further including a channel region having an impedance in relationship to the intensity of the radiation received by the gate region.

14. The JFET of claim 12, wherein the first gate region is formed between a channel region and a substrate.

15. The JFET of claim 14, wherein the radiation is received from a backside of the JFET formed in an integrated circuit.

16. The JFET of claim 12 further including a second gate region formed on an opposite side of the channel region as the first gate region, the second gate region is essentially floating.

17. A method for sensing radiation, comprising the steps of:
receiving radiation at a gate region of a junction field effect transistor (JFET), the gate region being essentially floating;
applying a bias potential to a source/drain region of the JFET; and
reading a potential provided by a drain/source region of the JFET.

18. The method of claim 17, wherein:
the gate region is formed between a channel region of the JFET and a substrate and the radiation is applied to a backside of the JFET formed in an integrated circuit.

19. The method of claim 17, wherein the step of reading further includes:
receiving the potential provided by the drain/source region at a first terminal of an amplifier circuit and receiving a reference potential at a second terminal of the amplifier circuit.

20. The method of claim 19, further including the step of:
providing the reference potential to a source/drain region to at least one other JFET.

21. The method of claim 19, wherein the step of reading further includes selectively providing the bias potential to a row line that is coupled to the source/drain of the JFET.

22. The method of claim 19, wherein the step of reading further includes:
selectively coupling a column that is connected to the drain/source region of the JFET to first terminal of the amplifier circuit.

23. A method for forming a radiation sensing device, comprising:
coupling a bias circuit to a first terminal of a radiation sensing pixel comprising a junction field effect transistor (JFET); and
coupling a signal output circuit to a second terminal of the radistion sensing pixel.

24. The method of claim 23, further comprising:
a plurality of radiation sensing pixels arranged in rows and columns, each radiation sensing pixel comprising a JFET; and
coupling the bias circuit to a first terminal of each of the plurality of radiation sensing pixels in one of the columns and coupling the signal output circuit to a second terminal of each of the plurality of radiation sensing pixels in one of the rows.

25. The method of claim 24, further including:
a plurality of read out circuits, each row is coupled to a corresponding one of the read out circuits.
